(19) United States
(12) Patent Application Publication
(10) Pub. No.: US 2026/0293192 A1
(43) Pub. Date: Sep. 24, 2026

(54) SEMICONDUCTOR DEVICE

(71) Applicants: KABUSHIKI KAISHA TOSHIBA, Kawasaki-shi (JP); Toshiba Electronic Devices & Storage Corporation, Kawasaki-shi (JP)

(72) Inventor: Kohei OASA, Chuo Tokyo (JP)

(73) Assignees: KABUSHIKI KAISHA TOSHIBA, Kawasaki-shi (JP); Toshiba Electronic Devices & Storage Corporation, Kawasaki-shi (JP)

(21) Appl. No.: 19/359,824

(22) Filed: Oct. 16, 2025

(30) Foreign Application Priority Data
Mar. 18, 2025 (JP) 2025-043162

(51) Int. Cl. H10D 30/63; H10D 62/10; H10D 62/60; H10D 64/00; H10D 64/23; H10D 64/27

(52) U.S. Cl. CPC H10D 30/63; H10D 62/102; H10D 62/60; H10D 64/112; H10D 64/117; H10D 64/2527; H10D 64/513

(57) ABSTRACT

A semiconductor device of an embodiment includes a semiconductor member, a source electrode, a drain electrode, a gate electrode, a first conductive portion, a second conductive portion, a first insulating portion, and a second insulating portion. The semiconductor member is provided with a first concave portion and a second concave portion, which are recessed from a surface in a first direction on a first side toward a second side. The source electrode is located on the first side of the semiconductor member. The drain electrode is located on the second side of the semiconductor member. The gate electrode is located in the first concave portion. At least a part of the first conductive portion is located in the second concave portion. The first conductive portion is connected to the source electrode. The second conductive portion is located in the second concave portion and on the second side of the first conductive portion. The first insulating portion insulates the semiconductor member from the gate electrode in the first concave portion. The second insulating portion insulates the semiconductor member, the source electrode, the first conductive portion, and the second conductive portion from each other in the second concave portion.

### CROSS-REFERENCE TO RELATED APPLICATION

This application is based upon and claims the benefit of priority from Japanese Patent Application No. 2025-043162, filed on Mar. 18, 2025; the entire contents of which are incorporated herein by reference.

### FIELD

Embodiments described herein relate generally to a semiconductor device.

### BACKGROUND

In a semiconductor device, by miniaturizing an operating region (device region), on-resistance can be reduced. However, if a field plate is refined, an electric field may increase at end portions of the field plate, resulting in leakage current.

### BRIEF DESCRIPTION OF THE DRAWINGS

FIG. 1 is a cross-sectional view schematically showing a semiconductor device of a first embodiment.

FIG. 2 is a cross-sectional perspective view schematically showing the semiconductor device of the first embodiment.

FIG. 3 is a cross-sectional view schematically showing a semiconductor device of a second embodiment.

FIG. 4 is a partial cross-sectional view showing a field plate portion, a floating portion, and a second insulating portion of Variant 1.

FIG. 5 is a partial cross-sectional view showing a field plate portion, a floating portion, and a second insulating portion of Variant 2.

FIG. 6 is a cross-sectional perspective view schematically showing a semiconductor device of a comparative example.

### DETAILED DESCRIPTION

A semiconductor device of an embodiment has a semiconductor member, a source electrode, a drain electrode, a gate electrode, a first conductive portion, a second conductive portion, a first insulating portion, and a second insulating portion. The semiconductor member is provided with a first concave portion and a second concave portion. The first concave portion and the second concave portion are recessed from a surface of the semiconductor member on a first side in a first direction to a second side opposite to the first side. The source electrode is located on the first side of the semiconductor member. The drain electrode is located on the second side of the semiconductor member. The gate electrode is located at least partially inside the first concave portion. The first conductive portion is located at least partially inside the second concave portion. The first conductive portion is connected to the source electrode. The second conductive portion is located on the second side of the first conductive portion in the second concave portion. The first insulating portion is located in the first concave portion. The first insulating portion insulates the semiconductor member from the gate electrode. The second insulating portion is located in the second concave portion. The second insulating portion insulates the semiconductor member, the first conductive portion, and the second conductive portion from each other.

Hereinafter, the semiconductor device of the embodiment will be described with reference to the accompanying drawings.

### First Embodiment

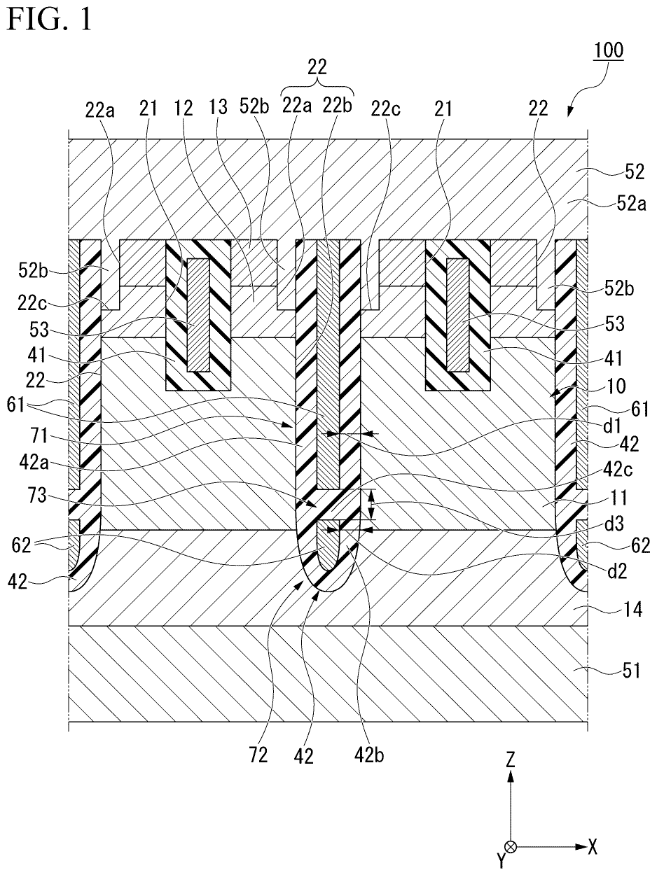

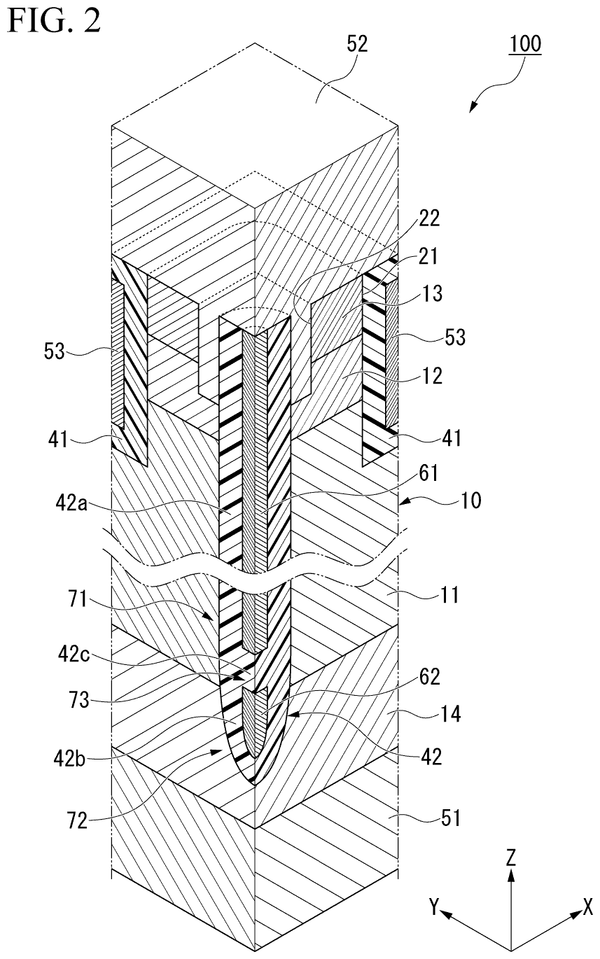

FIG. 1 is a cross-sectional view schematically showing a semiconductor device 100 of a first embodiment. FIG. 2 is a cross-sectional perspective view schematically showing the semiconductor device 100 of the first embodiment.

The drawings show an X axis, a Y axis, and a Z axis as appropriate. The X axis, the Y axis, and the Z axis are perpendicular to each other.

In this specification, a term “direction” is a concept that encompasses two directions (one side and the other side) that face opposite each other. In the following embodiment, a direction parallel to the Z axis corresponds to “a first direction,” a direction parallel to the X axis corresponds to “a second direction” and a direction parallel to the Y axis corresponds to “a third direction.” Accordingly, a first direction Z, a second direction X, and a third direction Y are three directions crossing each other. In the specification, a side (+Z) in the first direction Z facing an arrow of the Z axis is referred to as an upper side or a first side, and a side (−Z) in the first direction Z opposite to an arrow of the Z axis is referred to as a lower side or a second side. Further, in this specification, the concepts of “upper” and “lower” do not necessarily indicate a relationship with the direction of gravity.

In the following description, notations such as n, n⁺, n⁻, p, p⁺, p⁻, and the like, may be used. These notations represent a relative level in carrier concentration in each conductivity type. That is, n⁺ indicates that an n type carrier concentration is relatively higher than that of n, and n⁻ indicates that the n type carrier concentration is relatively lower than that of n.

As shown in FIG. 1, the semiconductor device 100 according to the embodiment includes a semiconductor member 10, a drain electrode 51, a source electrode 52, a gate electrode 53, a field plate portion (first conductive portion) 61, a floating portion (second conductive portion) 62, a first insulating portion 41, and a second insulating portion 42.

### Semiconductor Member

The semiconductor member 10 includes at least one selected from the group consisting of, for example, silicon (Si), a nitride semiconductor (for example, GaN or the like), silicon carbide (SiC), and an oxide semiconductor (for example, GaO).

The semiconductor member 10 is in the form of a substrate with the first direction Z as its thickness direction. The drain electrode 51 is located below the semiconductor member 10. In addition, the source electrode 52 is located above the semiconductor member 10. That is, the semiconductor member 10 is sandwiched between the drain electrode 51 and the source electrode 52 in the first direction Z. In addition, a direction from the drain electrode 51 to the source electrode 52 is along the first direction Z.

The semiconductor member 10 is provided with a plurality of groove portions (first concave portions) 21 and a plurality of concave portions (second concave portions) 22. The groove portions 21 and the concave portions 22 are recessed downward from an upper surface of the semiconductor member 10. The concave portions 22 are formed deeper than the groove portions 21.

As shown in FIG. 2, the groove portions 21 extend in a direction crossing the first direction Z (in the embodiment, the second direction X, or the third direction Y). The groove portions 21 are formed in, for example, a grid shape when seen in the first direction Z.

When seen in the first direction Z, the shape of the concave portion 22, for example, is approximately rectangular in an upper portion and approximately circular in a lower portion. Further, the shape of the concave portion 22 is not limited to the embodiment. The concave portions 22 are provided within a range surrounded by the groove portions 21 and divided by the groove portions 21 when seen in the first direction Z. The plurality of concave portions 22 are arranged in a direction perpendicular to the first direction Z (in the embodiment, the second direction X, or the third direction Y).

As shown in FIG. 1, step portions 22c directed upward are provided on inner side surfaces of the concave portions 22. The step portions 22c are provided on the inner side surface of the concave portions 22 over the entire circumference. The concave portions 22 have expansion portions 22a located above the step portions 22c, and contraction portions 22b located below the step portions 22c. An opening width of the concave portions 22 in the second direction X and the third direction Y is greater above the step portions 22c (i.e., the expansion portions 22a) than below the step portions 22c (i.e., the contraction portions 22b).

The semiconductor member 10 of the embodiment includes a first semiconductor region 11 of a first conductivity type, a second semiconductor region 12 of a second conductivity type, a third semiconductor region 13 of a first conductivity type, and a fourth semiconductor region 14. The first semiconductor region 11, the second semiconductor region 12, the third semiconductor region 13, and the fourth semiconductor region 14 are formed in a layered shape in the first direction Z. These semiconductor regions are disposed from top to bottom in the order of the third semiconductor region 13, the second semiconductor region 12, the first semiconductor region 11, and the fourth semiconductor region 14.

The first conductivity type and second conductivity type are either n type or p type. In the embodiment, the first conductivity type is an n type, and the second conductivity type is a p type. However, the first conductivity type may be a p type, and the second conductivity type may be an n type.

The first semiconductor region 11 is, for example, an n region. A part of the first semiconductor region 11 extends below the groove portion 21. The first semiconductor region 11 is located above a bottom portion of the concave portion 22. At least a part of the first semiconductor region 11 is located between the concave portions 22 adjacent to each other.

The second semiconductor region 12 is, for example, a p region. The second semiconductor region 12 is located above the first semiconductor region 11. The second semiconductor region 12 is located above a bottom portion of the groove portion 21 and a bottom portion of the concave portion 22. At least a part of the second semiconductor region 12 is located between the groove portion 21 and the concave portion 22 in the second direction X (or the third direction Y). In addition, at least a part of the second semiconductor region 12 is located between the source electrode 52 and the gate electrode 53 in the second direction X (or the third direction Y). The second semiconductor region 12 surrounds the field plate portion 61 in a plane (X-Y plane) perpendicular to the first direction Z.

The third semiconductor region 13 is, for example, an n⁺ region. A carrier concentration of a first conductivity type in the third semiconductor region 13 is higher than a carrier concentration of a first conductivity type in the first semiconductor region 11. The third semiconductor region 13 is located above the second semiconductor region 12. The third semiconductor region 13 is in contact with the source electrode 52. Accordingly, the third semiconductor region 13 is electrically connected to the source electrode 52. The third semiconductor region 13 surrounds the field plate portion 61 in the plane (X-Y plane) perpendicular to the first direction Z.

The fourth semiconductor region 14 is, for example, an n⁺ region. A carrier concentration of a first conductivity type in the fourth semiconductor region 14 is higher than a carrier concentration of a first conductivity type in the first semiconductor region 11. The fourth semiconductor region 14 is provided between the drain electrode 51 and the first semiconductor region 11 in the first direction Z. That is, the fourth semiconductor region 14 is located below the first semiconductor region 11.

The fourth semiconductor region 14 comes into contact with the drain electrode 51. The fourth semiconductor region 14 is electrically connected to the drain electrode 51. According to the embodiment, by providing the fourth semiconductor region 14 having a high carrier concentration in the semiconductor member 10, the resistance of the electrical connection between the drain electrode 51 and the semiconductor member 10 can be reduced. Accordingly, for example, the on-resistance of the semiconductor device 100 can be reduced.

In the embodiment, an upper end portion of the fourth semiconductor region 14 is located below a bottom portion of the groove portion 21 and located above a bottom portion (lower end portion) of the concave portion 22. At least a part of the fourth semiconductor region 14 is located between the neighboring concave portions 22.

The carrier concentration of the first conductivity type in the first semiconductor region 11 may be, for example, 1.0×10¹⁵ cm⁻³ or more and 1.0×10¹⁷ cm⁻³ or less. The carrier concentration of the second conductivity type in the second semiconductor region 12 may be, for example, 1.0×10¹⁶ cm⁻³ or more and 1.0×10¹⁸ cm⁻³ or less. The carrier concentration of the first conductivity type in the third semiconductor region 13 may be, for example, 3.0×10¹⁸ cm⁻³ or more and 3.0×10²⁰ cm⁻³ or less. The carrier concentration of the first conductivity type in the fourth semiconductor region 14 may be, for example, 1.0×10¹⁷cm⁻³ or more and 3.0×10²⁰ cm⁻³ or less.

### Drain Electrode

The drain electrode 51 is located below the semiconductor member 10. The drain electrode 51 covers a lower surface of the semiconductor member 10. The drain electrode 51 contains at least one selected from the group consisting of, for example, Al, Cu, Mo, W, Ta, Co, Ru, Ti, Ni, Au, and Pt.

### Source Electrode

The source electrode 52 is located above the semiconductor member 10. The source electrode 52 has an interconnection layer 52a, and a contact portion 52b. The source electrode 52 contains at least one selected from the group consisting of, for example, Ti, TiN, Ni, W, Mo, Ta, Zr, Al, Au, Sn, V, Re, Os, Ir, Pt, Pd, Rh, Ru, Nb, Sr and Hf.

The contact portion 52b is located in the concave portion 22. That is, a part of the source electrode 52 of the embodiment is located in the concave portion 22. In the embodiment, the contact portion 52b is located above the step portion 22c of the concave portion 22. The contact portion 52b surrounds the field plate portion 61 in the plane (X-Y plane) perpendicular to the first direction Z.

The interconnection layer 52a is located above the contact portion 52b and connected to the contact portion 52b. In addition, the interconnection layer 52a covers an upper surface of the semiconductor member 10.

### Gate Electrode

The gate electrode 53 is located in the groove portion 21. At least a part of the gate electrode 53 may be located in the groove portion 21. As shown in FIG. 2, the gate electrode 53 extends in the groove portion 21 in a direction in which the groove portion 21 extends. That is, the gate electrode 53 extends in a direction crossing the first direction Z (in the embodiment, the second direction X, or the third direction Y). The gate electrode 53 and the contact portion 52b are arranged side by side in the second direction X.

The gate electrode 53 contains, for example, conductive silicon, polysilicon, tungsten, titanium, or, titanium nitride. The gate electrode 53 is insulated from the semiconductor member 10.

In the semiconductor device 100 of the embodiment, current flowing between the drain electrode 51 and the source electrode 52 is controlled by the potential of the gate electrode 53. The potential of the gate electrode 53 is based on the potential of, for example, the source electrode 52.

### Field Plate Portion

The field plate portion 61 is located in the concave portion 22. At least a part of the field plate portion 61 may be located in the concave portion 22.

The field plate portion 61 is formed of a conductive material. The field plate portion 61 contains, for example, conductive silicon, polysilicon, tungsten, titanium, or titanium nitride. The field plate portion 61 is insulated from the semiconductor member 10.

The field plate portion 61 is formed in a columnar shape extending in the first direction Z in the concave portion 22. In the embodiment, the field plate portion 61 has a cylindrical shape, but may have other shapes such as a polygonal prism or the like. In the embodiment, a lower end portion of the field plate portion 61 has a substantially planar shape extending along a plane perpendicular to the first direction Z. However, the lower end portion of the field plate portion 61 may have a curved shape such as a hemispherical shape or the like.

An upper end portion of the field plate portion 61 is connected to the interconnection layer 52a of the source electrode 52. Accordingly, the field plate portion 61 is electrically connected to the source electrode 52 and is at the same potential as the source electrode 52. In the embodiment, while the field plate portion 61 comes into direct contact with the source electrode 52 and is connected to the source electrode 52, the field plate portion 61 and the source electrode 52 may be connected via, for example, an interconnection portion.

### Floating Portion (Second Conductive Portion)

The floating portion 62 is located in the concave portion 22. The floating portion 62 is located below the field plate portion 61.

The floating portion 62 is formed of a conductive material. The floating portion 62 is formed of, for example, the same material as the field plate portion 61. That is, the floating portion 62 contains, for example, conductive silicon, polysilicon, tungsten, titanium, or, titanium nitride. The floating portion 62 is insulated from the semiconductor member 10 and the field plate portion 61.

The floating portion 62 has a columnar shape extending in the first direction Z in the concave portion 22. In the embodiment, the floating portion 62 may have a cylindrical shape, but may have other shapes such as a polygonal prism or the like. In the embodiment, an upper end portion of the floating portion 62 has a substantially planar shape extending along a plane perpendicular to the first direction Z. However, the lower end portion of the floating portion 62 may have a curved shape such as a hemispherical shape or the like. In the embodiment, the lower end portion of the floating portion 62 has a hemispherical shape. However, the lower end portion of the floating portion 62 may have a planar shape.

### First Insulating Portion

The first insulating portion 41 is located in the groove portion 21. The first insulating portion 41 surrounds the gate electrode 53. The first insulating portion 41 insulates the semiconductor member 10 from the gate electrode 53. In addition, first insulating portion 41 insulates the gate electrode 53 from the source electrode 52. The first insulating portion 41 of the embodiment functions as a so-called gate insulating film. The first insulating portion 41 contains at least one selected from the group consisting of, for example, silicon oxide, silicon nitride, and silicon oxynitride.

### Second Insulating Portion

The second insulating portion 42 is located in the concave portion 22. The second insulating portion 42 insulates the field plate portion 61 and the floating portion 62 from the semiconductor member 10, and insulates the field plate portion 61 and the floating portion 62 from each other. The second insulating portion 42 contains at least one selected from the group consisting of, for example, silicon oxide, silicon nitride, and silicon oxynitride.

As shown in FIG. 2, the second insulating portion 42 includes a first insulating region 42a, a second insulating region 42b, and a third insulating region 42c.

The first insulating region 42a of the embodiment is located between the field plate portion 61 and the semiconductor member 10 in the second direction X and the third direction Y. The first insulating region 42a has a cylindrical shape. The first insulating region 42a comes into contact with the field plate portion 61 and the semiconductor member 10. The first insulating region 42a surrounds the field plate portion 61 in the plane (X-Y plane) perpendicular to the first direction Z.

The first insulating region 42a, and the semiconductor member 10 and the field plate portion 61 facing each other via the first insulating region 42a constitute a pseudo capacitor. Here, the capacitor constituted by the first insulating region 42a, the semiconductor member 10, and the field plate portion 61 is referred to as a first virtual capacitor 71. The first virtual capacitor 71 is a concentric cylindrical capacitor.

The second insulating region 42b of the embodiment is located between the floating portion 62 and the semiconductor member 10 in the second direction X and the third direction Y. The second insulating region 42b is located below the first insulating region 42a. The second insulating region 42b has a cylindrical shape. The second insulating region 42b comes into contact with the floating portion 62 and the semiconductor member 10. The second insulating region 42b surrounds the floating portion 62 in the plane (X-Y plane) perpendicular to the first direction Z.

The second insulating region 42b, and the semiconductor member 10 and the floating portion 62 facing each other via the second insulating region 42b constitute a pseudo capacitor. Here, the capacitor constituted by the second insulating region 42b, the semiconductor member 10, and the floating portion 62 is referred to as a second virtual capacitor 72. The second virtual capacitor 72 has a lower end portion which is a hemispherical concentric spherical capacitor and an upper portion which is a concentric cylindrical capacitor, which are connected in parallel.

The third insulating region 42c is located between the field plate portion 61 and the floating portion 62 in the first direction Z. The third insulating region 42c has a flat plate shape with its thickness direction being the first direction Z. The third insulating region 42c is located below the first insulating region 42a and above the second insulating region 42b. The third insulating region 42c comes into contact with the field plate portion 61 and the floating portion 62.

The third insulating region 42c, and the field plate portion 61 and the floating portion 62 facing each other via the third insulating region 42c constitute a pseudo capacitor. Here, the capacitor constituted by the third insulating region 42c, the field plate portion 61 and the floating portion 62 is referred to as a third virtual capacitor 73. The third virtual capacitor 73 is a parallel plate capacitor.

### Effects of First Embodiment

The semiconductor device 100 of the embodiment includes the semiconductor member 10, the source electrode 52, the drain electrode 51, the gate electrode 53, the field plate portion 61, the floating portion 62, the first insulating portion 41, and the second insulating portion 42. The semiconductor member 10 is provided with the groove portions 21 and the concave portions 22. The groove portions 21 and the concave portions 22 are recessed downward from the upper surface of the semiconductor member 10. The source electrode 52 is located above the semiconductor member 10. The drain electrode 51 is located below the semiconductor member 10. At least a part of the gate electrode 53 is located in the groove portion 21. At least a part of the field plate portion 61 is located in the concave portion 22. The field plate portion 61 is connected to the source electrode 52. The floating portion 62 is located below the field plate portion 61 in the concave portion 22. The first insulating portion 41 is located in the groove portion 21. The first insulating portion 41 insulates the semiconductor member 10 from the gate electrode 53. The second insulating portion 42 is located in the concave portion 22. The second insulating portion 42 insulates the semiconductor member 10, the field plate portion 61, and the floating portion 62 from each other.

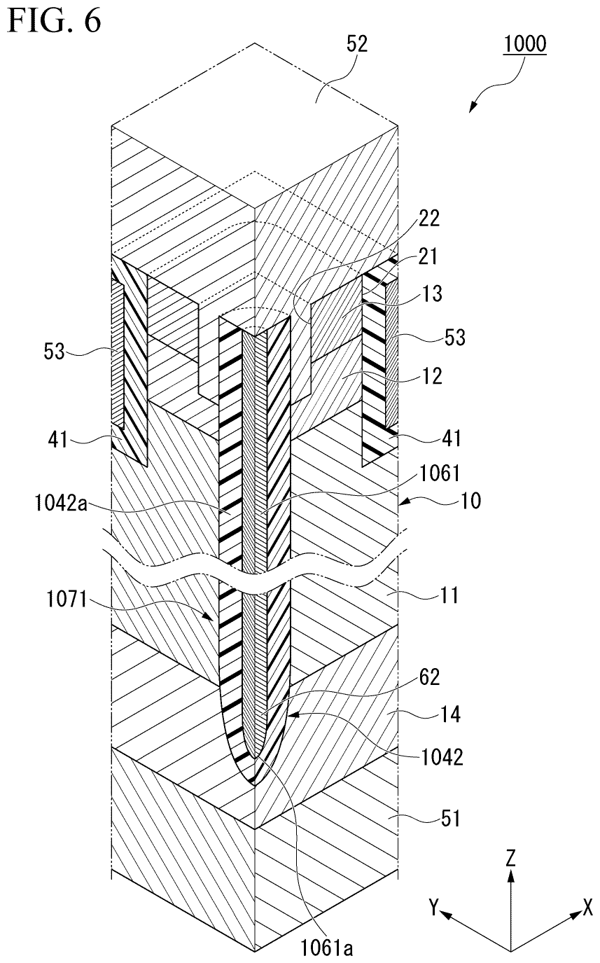

FIG. 6 is a cross-sectional perspective view of a semiconductor device 1000 of a comparative example in order to describe advantages of the embodiment. Further, in the comparative example, the same components as in the embodiment are designated by the same reference signs, and description thereof will be omitted.

The semiconductor device 1000 of the comparative example does not have the floating portion 62, compared to the semiconductor device 100 of the present embodiment. In the semiconductor device 1000 of the comparative example, the concave portion 22 is provided with a field plate portion 1061 extending to the vicinity of the bottom portion of the concave portion 22. The field plate portion 1061 has a cylindrical shape extending in the first direction Z. In addition, a lower end portion 1061a of the field plate portion 1061 is curved in a hemispherical shape.

The semiconductor device 1000 of the comparative example has a second insulating portion 1042 provided in the concave portions 22, like the semiconductor device 100 of the embodiment. The second insulating portion 1042 has a first insulating region 1042a located between the field plate portion 1061 and the semiconductor member 10. The first insulating region 1042a surrounds the field plate portion 1061 in the plane (X-Y plane) perpendicular to the first direction Z and covers the lower end portion 1061a of the field plate portion 1061 from below.

In the semiconductor device 1000 of the comparative example, the first insulating region 1042a, and the semiconductor member 10 and the field plate portion 1061 facing each other via the first insulating region 1042a constitute a pseudo capacitor. Here, a virtual capacitor 1071 constituted by the first insulating region 1042a, the semiconductor member 10, and the field plate portion 1061 has a hemispherical 3-dimensional shape at the lower end portion 1061a of the field plate portion 1061.

It is generally known that an electric field applied to a capacitor electrode is inversely proportional to a surface area of the electrode. In the virtual capacitor 1071 of the comparative example, the field plate portion 1061 that constitutes the electrode has a hemispherical shape at the lower end portion 1061a. For this reason, the electric field applied to the lower end portion 1061a of the field plate portion 1061 is inversely proportional to the square of the radius of the field plate portion 1061. That is, in the semiconductor device 1000 of the comparative example, as the radius of the field plate portion 1061 is reduced to make the semiconductor device 1000 finer, the electric field applied to the lower end portion of the field plate portion 1061 increases exponentially at a squared rate, making leakage current more likely to occur.

On the other hand, according to the semiconductor device 100 of the embodiment shown in FIG. 2, the floating portion 62 is provided below the field plate portion 61 in the concave portion 22 of the semiconductor member 10. In the embodiment, the floating portion 62 capacitively couples with the semiconductor member 10 as the second virtual capacitor 72. For this reason, the potential of the floating portion 62 is a potential between the potential of the semiconductor member 10 around the floating portion 62 (in the embodiment, the fourth semiconductor region 14) and the potential of the field plate portion 61 (intermediate potential). That is, according to the embodiment, the potential of the floating portion 62 is brought close to the potential of the drain electrode 51. For this reason, the potential difference applied to the second insulating portion 42 at the bottom portion of the concave portion 22 can be reduced, and current leakage between the floating portion 62 and the semiconductor member 10 at the bottom portion of the concave portion 22 can be suppressed. In addition, in the embodiment, the field plate portion 61 capacitively couples with the semiconductor member 10 as the first virtual capacitor 71. The first virtual capacitor 71 is a concentric cylindrical capacitor and is less susceptible to electric field concentration compared to the virtual capacitor 1071 of the comparative example. According to the embodiment, it is possible to suppress the current leak between the field plate portion 61 and the semiconductor member 10.

In the semiconductor device 100 of the embodiment, the field plate portion 61 has a cylindrical shape extending in the first direction Z. According to the embodiment, as described above, leakage current from the lower end portion of the field plate portion 61 can be suppressed while miniaturizing the semiconductor device 100. Further, the structure in which the floating portion 62 is disposed below the field plate portion 61 has the effect of reducing the electric field not only when the field plate portion 61 has a cylindrical shape, but also when the field plate portion extends in stripes. As an example, in a semiconductor device having a striped field plate portion whose cross section shown in FIG. 1 extends along the third direction Y, the shape of the lower end portion of the field plate portion is a cylindrical surface that is convex downward. For this reason, in a semiconductor device that does not have a floating portion, the electric field in the lower end portion of the field plate portion increases inversely proportional to the radius of the field plate portion. On the other hand, when the floating portion is provided below the striped field plate portion, the electric field in the lower end portion of the field plate portion 61 is independent of the radius of the field plate portion. That is, even in the case of having the striped field plate portion, by providing the floating portion, the concentration of electric field lines in the lower end portion of the field plate portion that accompanies miniaturization of semiconductor devices can be suppressed.

In the embodiment, the lower end portion of the floating portion 62 is located below the upper end portion of the fourth semiconductor region 14. The fourth semiconductor region 14 has a high carrier concentration and is therefore connected to the drain electrode 51 with low resistance. For this reason, the potential of the fourth semiconductor region 14 is close to the drain electrode 51. According to the embodiment, by overlapping the position of the floating portion 62 in the first direction Z with the position of the fourth semiconductor region 14 in the first direction Z, the potential of the floating portion 62 can be brought closer to the potential of the drain electrode 51. Accordingly, the potential difference applied to the second insulating portion 42 at the bottom portion of the concave portion 22 can be reduced, and current leakage between the floating portion 62 and the semiconductor member 10 at the bottom portion of the concave portion 22 can be suppressed.

Here, a capacitance of the second virtual capacitor 72 (i.e., a capacitance between the floating portion 62 and the semiconductor member 10) is referred to as a second capacitance Cd. A capacitance of the third virtual capacitor 73 (i.e., a capacitance between the field plate portion 61 and the floating portion 62) is referred to as a third capacitance Cp.

The capacitance of each virtual capacitor can be calculated from a dielectric constant of an insulating region between the conductive portion and the semiconductor member, a film thickness of the insulating region, and a facing area between the conductive portion and the semiconductor member. When the conductive portion and the surface shape of the semiconductor member are complicated, the capacitance can be calculated by performing a simulation based on these numerical values.

In addition, a potential of a portion of the semiconductor member 10 facing the floating portion 62 via the second insulating portion 42 is referred to as a reference potential Vd. In the embodiment, the semiconductor member 10 faces the floating portion 62 in the fourth semiconductor region 14. The potential of the fourth semiconductor region 14 is substantially equal to the potential of the drain electrode 51. For this reason, in the embodiment, the reference potential Vd is substantially equal to the potential of the drain electrode 51. Further, if the potential of the portion of semiconductor member 10 facing the floating portion 62 via the second insulating portion 42 is not uniform, the reference potential is the maximum value of the potential of the portion of the semiconductor member 10 facing the floating portion 62, which is the reference potential Vd. Further, the reference potential Vd can be calculated from the withstand voltage of the semiconductor member 10.

In the semiconductor device 100 of the embodiment, the second capacitance Cd is greater than the third capacitance Cp. In other words, a capacitance between the floating portion 62 and the semiconductor member 10 (the second capacitance Cd) is greater than a capacitance between the field plate portion 61 and the floating portion 62 (the third capacitance Cp). That is, the second capacitance Cd and the third capacitance Cp have a relationship of the following formula.

$$Cd > Cp$$

Here, a potential Vf of the floating portion 62 is expressed by the following equation using the second capacitance Cd, the third capacitance Cp, and the reference potential Vd.

$$Vf = Vd \times \{ Cd / ( Cp + Cd ) \}$$

When the second capacitance Cd and the third capacitance Cp satisfy the above-mentioned relationship (Cd>Cp), the potential Vf of the floating portion 62 is equal to or greater than ½ of the reference potential Vd (Vf>Vd×½). That is, the capacitive coupling between the floating portion 62 and the semiconductor member 10 can bring the potential of the floating portion 62 closer to the potential of the semiconductor member 10 (the reference potential Vd), thereby enhancing the effect of suppressing leakage current from the floating portion 62 to the semiconductor member 10.

In the embodiment, if a film thickness d3 of the third insulating region 42c is made too thin, the electric field between the field plate portion 61 and the floating portion 62 may become too strong, resulting in a dielectric breakdown of the third insulating region 42c. Here, when the permissible electric field of the member constituting the third insulating region 42c is Emax, it is preferable that the film thickness d3 satisfy the following formula.

$$d 3 > Vd \times \{ Cd / ( Cp + Cd ) \} / Em ax$$

The dielectric breakdown of the third insulating region 42c can be suppressed when the film thickness d3 of the third insulating region 42c satisfies the following formula. Further, here, the film thickness d3 of the third insulating region 42c means a minimum thickness dimension in the first direction Z of the third insulating region 42c located between the field plate portion 61 and the floating portion 62.

In the semiconductor device 100 of the embodiment, the lower end portion of the floating portion 62 has a curved shape with a downward convex hemispherical shape. When the lower end portion of the floating portion 62 is a flat surface, electric field lines are more likely to be concentrated at corners of the lower end portion of the floating portion 62. According to the embodiment, by making the lower end portion of the floating portion 62 curved, the concentration of the electric field lines can be suppressed and leakage current can be suppressed from occurring at the lower end portion of the floating portion 62.

Next, the procedure for forming the field plate portion 61, the floating portion 62, and the second insulating portion 42 of this embodiment will be described. First, the upper surface of the semiconductor member 10 is etched by an etching method to form the concave portions 22. Next, for example, the insulating film is formed on the inner surface of the concave portion 22 by chemical vapor deposition. The insulating film constitutes a part of the first insulating region 42a and the second insulating region 42b. Next, for example, after the concave portions 22 are filled with a conductive material, such as polysilicon or the like, by chemical vapor deposition, a portion of the conductive material is removed by etching, leaving the conductive material at the bottom portion of the concave portion 22. Accordingly, the floating portion 62 made of a conductive material is formed on the bottom portion of the concave portion 22. Next, for example, the insulating film is formed on the surface of the floating portion 62 and the inner surface of the concave portion 22 above the floating portion 62 by chemical vapor deposition. The insulating film constitutes a part of the first insulating region 42a and the third insulating region 42c. Next, if necessary, the insulating film is etched to adjust the film thickness of the first insulating region 42a and the third insulating region 42c (film thickness adjusting process). Next, for example, the field plate portion 61 is formed in the concave portion 22 and above the floating portion 62 by chemical vapor deposition.

In the floating portion 62 of the embodiment, a film thickness d1 of the first insulating region 42a is equal to a film thickness d2 of the second insulating region 42b by the above-mentioned film thickness adjusting process. That is, in the embodiment, the film thickness d1 of the first insulating region 42a is equal to the film thickness d2 of the second insulating region 42b. However, the film thickness d1 of the first insulating region 42a and the film thickness d2 of the second insulating region 42b may be different from each other. The case in which the film thickness d1 of the first insulating region 42a and the film thickness d2 of the second insulating region 42b are different from each other will be described as Variant 1 and Variant 1 below.

Next, the film thickness d1 of the first insulating region 42a means a thickness dimension of the first insulating region 42a between the field plate portion 61 and the semiconductor member 10. Similarly, the film thickness d2 of the second insulating region 42b means a thickness dimension of the second insulating region 42b between the floating portion 62 and the semiconductor member 10.

### Second Embodiment

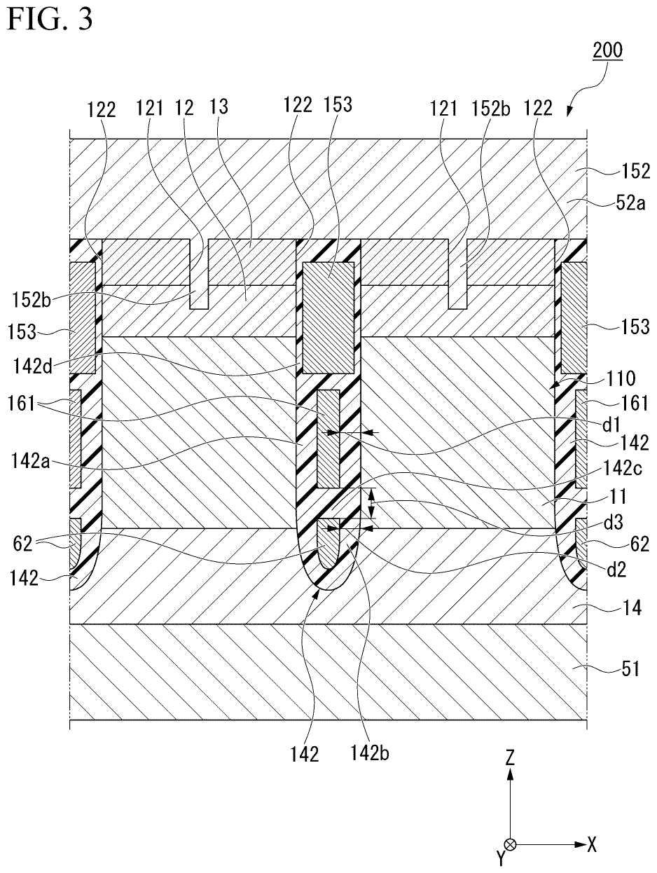

FIG. 3 is a cross-sectional view schematically showing a semiconductor device 200 of a second embodiment.

Next, in description of the second embodiment, the same components as in the first embodiment are designated by the same reference signs, and description thereof will be omitted.

Like the above-mentioned embodiment, the semiconductor device 200 includes a semiconductor member 110, a drain electrode 51, a source electrode 152, a gate electrode 153, a field plate portion (first conductive portion) 161, a floating portion 62, and an insulating portion (second insulating portion) 142.

Like the above-mentioned embodiment, the semiconductor member 110 includes the first semiconductor region 11, the second semiconductor region 12, the third semiconductor region 13, and the fourth semiconductor region 14. The semiconductor member 110 is provided with a plurality of first groove portions 121 and a plurality of second groove portions (concave portions) 122. The first groove portions 121 and the second groove portions 122 are recessed downward from an upper surface of the semiconductor member 110. The second groove portions 122 are formed deeper than the first groove portions 121. The first groove portions 121 and the second groove portions 122 each extend in the third direction Y. The first groove portions 121 and the second groove portions 122 are arranged alternately in the second direction X.

The source electrode 152 is located above the semiconductor member 110. The source electrode 152 has an interconnection layer 52a, and a contact portion 152b. The contact portion 152b is located in the first groove portion 121.

The gate electrode 153 is located in the second groove portion 122. At least a part of the gate electrode 153 may be located in the second groove portion 122. The gate electrode 153 and the contact portion 152b are disposed side by side in the second direction X.

The field plate portion 161 is located in the second groove portion 122 and below the gate electrode 153. The floating portion 62 is located in the second groove portion 122 and below the field plate portion 161. Accordingly, the gate electrode 153, the field plate portion 161, and the floating portion 62 are aligned from top to bottom within the second groove portion 122.

The field plate portion 161 and the floating portion 62 are both composed of a conductive material. The field plate portion 161 and the floating portion 62 both have a columnar shape extending in the first direction Z. The field plate portion 161 is connected to the source electrode 152 via an interconnection portion (not shown). Accordingly, the field plate portion 161 is at the same potential as the source electrode 152.

The insulating portion 142 is located in the second groove portion 122. The insulating portion 142 insulates the semiconductor member 110, the gate electrode 153, the field plate portion 161, and the floating portion 62 from each other.

The insulating portion 142 includes a first insulating region 142a, a second insulating region 142b, a third insulating region 142c, and a fourth insulating region 142d. The first insulating region 142a is located between the field plate portion 161 and the semiconductor member 110. The second insulating region 142b is located between the floating portion 62 and the semiconductor member 110. The third insulating region 142c is located between the field plate portion 161 and the floating portion 62. The fourth insulating region 142d surrounds the gate electrode 153. The fourth insulating region 142d insulates the gate electrode 153 from the semiconductor member 110, the source electrode 152, and the field plate portion 161.

### Effects of Second Embodiment

The semiconductor device 200 of the embodiment includes the semiconductor member 110, the source electrode 152, the drain electrode 51, the gate electrode 153, the field plate portion 161, the floating portion 62, and the insulating portion 142. The semiconductor member 110 is provided with the second groove portions 122. The second groove portions 122 are recessed downward from an upper surface of the semiconductor member 110. The source electrode 152 is located above the semiconductor member 110. The drain electrode 51 is located below the semiconductor member 110. At least a part of the gate electrode 153 is located in the second groove portion 122. The field plate portion 161 is located in the second groove portion 122 and below the gate electrode 153. The field plate portion 161 is connected to the source electrode 152. The floating portion 62 is located in the second groove portion 122 and below the field plate portion 161. The insulating portion 142 is located in the second groove portion 122. The insulating portion 142 insulates the semiconductor member 110, the gate electrode 153, the field plate portion 161, and the floating portion 62 from each other.

According to the semiconductor device 200 of the embodiment, like the above-mentioned embodiment, the floating portion 62 is capacitively coupled to the semiconductor member 110. For this reason, the potential of the floating portion 62 is made close to the potential of the semiconductor member 110 (in this embodiment, the fourth semiconductor region 14) surrounding the floating portion 62. Eventually, the generation of the electric field concentration in the insulating portion 142 at the bottom portion of the second groove portion 122 can be suppressed, and the generation of leakage current at the bottom portion of the second groove portions 122 can be suppressed.

### Variants

Next, variants that can be adopted in the above-mentioned embodiment will be described. Further, in the following description of each variant, components that are the same as those in the embodiment or variant already described will be designated by the same reference signs and description thereof will be omitted. In addition, in the following description, the structure of each variant will be described as being adopted in the first embodiment, but a similar structure can also be adopted in the second embodiment.

### Variant 1

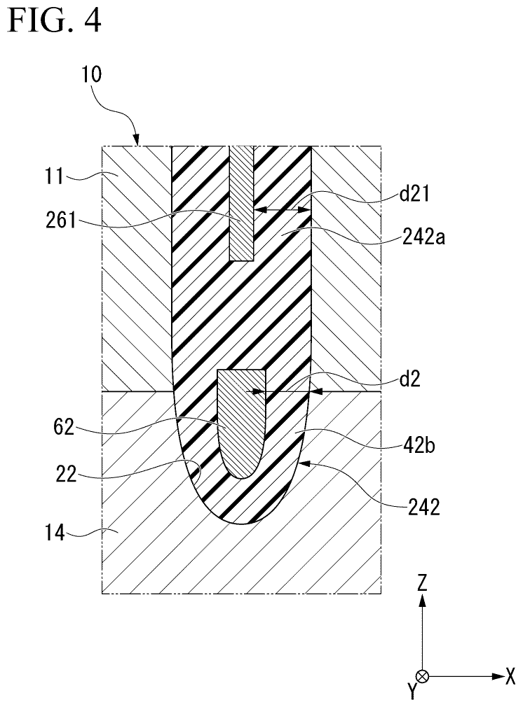

FIG. 4 is a partial cross-sectional view showing a field plate portion 261, a floating portion 62, and a second insulating portion 242 of Variant 1. A diameter of the field plate portion 261 of the variant is smaller than a diameter of the floating portion 62. In addition, a film thickness d21 of a first insulating region 242a is greater than the film thickness d2 of the second insulating region 42b.

In the manufacturing process of the semiconductor device 100, if the above-mentioned film thickness adjusting process is omitted, the film thickness d21 of the first insulating region 242a will be greater than the film thickness d2 of the second insulating region 42b. That is, according to the variant, some processes can be omitted, and the manufacturing process of the semiconductor device 100 can be simplified.

### Variant 2

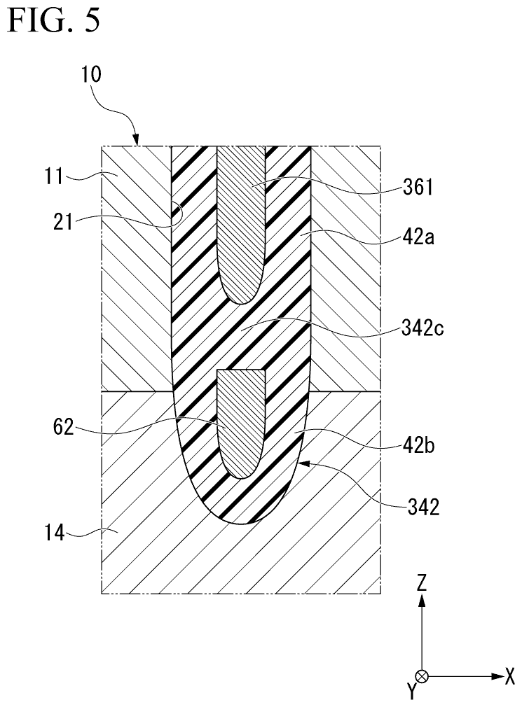

FIG. 5 is a partial cross-sectional view showing a field plate portion 361, a floating portion 62, and a second insulating portion 342 of Variant 2. A lower end portion of the field plate portion 361 of the variant has a curved shape with a hemispherical shape protruding downward. When the lower end portion of the field plate portion 361 is a flat surface, electric field lines tend to become concentrated at the corners of the lower end portion of the field plate portion 361. According to the variant, by making the lower end portion of the field plate portion 361 have a curved shape, the concentration of the electric field lines can be suppressed and leakage current can be suppressed from occurring at the lower end portion of the field plate portion 361.

In the manufacturing process of the semiconductor device 100 of Variant 2, during the above-mentioned film thickness adjusting process, isotropic etching such as chemical dry etching is performed to give an upper surface of a third insulating region 342c a downwardly convex curved shape. Accordingly, a lower end of the field plate portion 361 formed above the third insulating region 342c can be a curved shape along the upper surface of the third insulating region 342c.

According to at least one of the embodiments described above, by providing the floating portion 62 below the field plate portion 61, 161, 261 or 361, it is possible to provide the semiconductor device 100 capable of suppressing leakage current.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor member provided with a first concave portion and a second concave portion recessed from a surface in a first direction on a first side to a second side opposite to the first side;
a source electrode located on the first side of the semiconductor member;
a drain electrode located on the second side of the semiconductor member;
a gate electrode, at least a part of which is located in the first concave portion;
a first conductive portion, at least a part of which is located in the second concave portion and connected to the source electrode;
a second conductive portion located in the second concave portion and on the second side of the first conductive portion;
a first insulating portion located in the first concave portion and configured to insulate the semiconductor member from the gate electrode; and
a second insulating portion located in the second concave portion and configured to insulate the semiconductor member, the first conductive portion, and the second conductive portion from each other.

2. The semiconductor device according to claim 1, wherein the first conductive portion has a cylindrical shape extending in the first direction.

3. A semiconductor device comprising:
a semiconductor member provided with a concave portion recessed from a surface in a first direction on a first side to a second side opposite to the first side;
a source electrode located on the first side of the semiconductor member;
a drain electrode located on the second side of the semiconductor member;
a gate electrode, at least a part of which is located in the concave portion;
a first conductive portion located in the concave portion and on the second side of the gate electrode to be connected to the source electrode;
a second conductive portion located in the concave portion and on the second side of the first conductive portion; and
a second insulating portion located in the concave portion and configured to insulate the semiconductor member, the gate electrode, the first conductive portion, and the second conductive portion from each other.

4. The semiconductor device according to claim 1, wherein the semiconductor member includes:
a first semiconductor region of a first conductivity type;
a second semiconductor region of a second conductivity type; and
a third semiconductor region of the first conductivity type,
the second semiconductor region is located on the first side of the first semiconductor region, and at least a part thereof is located between the source electrode and the gate electrode in a second direction perpendicular to the first direction, and
the third semiconductor region is located on the first side of the second semiconductor region and electrically connected to the source electrode.

5. The semiconductor device according to claim 4, wherein the semiconductor member includes a fourth semiconductor region of the first conductivity type,
the fourth semiconductor region is located on the second side of the first semiconductor region and electrically connected to the drain electrode,
a carrier concentration of the first conductivity type in the fourth semiconductor region is higher than a carrier concentration of the first conductivity type in the first semiconductor region, and
an end portion of the second conductive portion on the second side is located on the second side of the end portion of the fourth semiconductor region on the first side.

6. The semiconductor device according to claim 1, wherein the second insulating portion includes:
a first insulating region located between the first conductive portion and the semiconductor member; and
a second insulating region located between the second conductive portion and the semiconductor member, and
a thickness dimension of the first insulating region between the first conductive portion and the semiconductor member is smaller than a thickness dimension of the second insulating region between the second conductive portion and the semiconductor member.

7. The semiconductor device according to claim 1, wherein the second insulating portion includes:
a first insulating region located between the first conductive portion and the semiconductor member; and
a second insulating region located between the second conductive portion and the semiconductor member, and
a thickness dimension of the first insulating region between the first conductive portion and the semiconductor member is greater than a thickness dimension of the second insulating region between the second conductive portion and the semiconductor member.

8. The semiconductor device according to claim 1, wherein an end portion of the first conductive portion on the second side has a curved shape protruding toward the second side.

9. The semiconductor device according to claim 1, wherein the second insulating portion includes a second insulating region located between the second conductive portion and the semiconductor member, and
a capacitance between the second conductive portion and the semiconductor member is greater than a capacitance between the first conductive portion and the second conductive portion.

10. The semiconductor device according to claim 1, wherein the second insulating portion includes a third insulating region located between the first conductive portion and the second conductive portion, and
provided that a capacitance between the second conductive portion and the semiconductor member is set as Cd,
a capacitance between the first conductive portion and the second conductive portion is set as Cp,
a potential of a portion of the semiconductor member facing the second conductive portion via the second insulating portion is set as Vd, and
a permissible electric field of a member that constitutes the third insulating region is set as Emax,
a film thickness d3 of the third insulating region satisfies the following formula.
$$d 3 > Vd \times \{ Cd / ( Cp + Cd ) \} / Emax .$$
